(19) United States
(12) Patent Application Publication
(10) Pub. No.: US 2018/0275179 A1
(43) Pub. Date: Sep. 27, 2018

(54) DETECTION DEVICE AND DETECTION METHOD

(71) Applicant: Realtek Semiconductor Corporation, Hsinchu (TW)

(72) Inventors: Rui WANG, Jiangsu Province (CN); Qi-Cai TANG, Jiangsu Province (CN); He LI, Jiangsu Province (CN); Jin-Jun XIA, Jiangsu Province (CN)

(21) Appl. No.: 15/686,158

(22) Filed: Aug. 25, 2017

(30) Foreign Application Priority Data
Mar. 24, 2017 (CN) 201710182110.8
Jun. 28, 2017 (CN) 201710507461.1

(51) Int. Cl. G01R 27/08; G01R 19/25

(52) U.S. Cl. CPC G01R 27/08; G01R 19/2513

(57) ABSTRACT

A detection device for a power over Ethernet (POE) system includes a detection circuit and a control circuit. The detection circuit provides a first test current to a powered device (PD) of the POE system, and measures multiple first voltage values after the PD that receives the first test current and before the PD reaches a steady state. The control circuit controls the detection circuit to provide the test current to the PD, and determines a number of test currents used by the detection device in the steady state according to the first voltage values.

### RELATED APPLICATIONS

This application claims priority to Chinese Application Serial Number 201710182110.8, filed Mar. 24, 2017, and Chinese Application Serial Number 201710507461.1, filed Jun. 28, 2017, which are herein incorporated by reference.

### BACKGROUND

### Technical Field

The present disclosure relates to a detection device and a detection method. More particularly, the present disclosure relates to a detection device and a detection method for a power over Ethernet (POE) system.

### Description of Related Art

In a power over Ethernet (POE) system, because an equivalent resistance and an equivalent capacitance of a powered device (PD) are unknown, a measurement may be made in a situation where the PD does not reach a steady state when the equivalent resistance and the equivalent capacitance are to be measured, which therefore results in an error in the measured signature resistance of the powered device.

### SUMMARY

An aspect of the present disclosure is to provide a detection device for a power over Ethernet (POE) system, and the detection device includes a detection circuit and a control circuit. The detection circuit provides a first test current to a powered device (PD) of the POE system, and to measure multiple first voltage values after the PD receives the first test current and before the PD reaches a steady state. The control circuit controls the detection circuit to provide the first test current to the PD, and to determine a number of test currents used by the detection device in the steady state according to the first voltage values.

An aspect of the present disclosure is to provide a detection device for a POE system. The detection device includes a detection circuit and a control circuit. The detection circuit includes a resistor, provides a test voltage to a PD of the POE system, and measures multiple first current values or first voltage values after the PD receives the test voltage and before the PD reaches a steady state. The control circuit determines a first resistance of the resistor, controls the detection circuit to provide the test voltage to the PD, and determines a number of test resistances used by the detection device in the steady state according to the first current values.

An aspect of the present disclosure is to provide a detection method for a POE system. The detection methods includes the following steps: controlling a detection circuit by a control circuit to provide a first test current to a PD of the POE system; and determining a number of test currents used by the detection device in the steady state according to the first voltage values by the control circuit.

### BRIEF DESCRIPTION OF THE DRAWINGS

FIG. 1 is a schematic diagram of a detection device according to an embodiment of the present disclosure;

FIG. 2 is a schematic diagram of a detection device according to an embodiment of the present disclosure;

FIG. 3 is a schematic diagram of measurements according to an embodiment of the present disclosure; and

FIG. 4 is a flow chart illustrating a detection method according to an embodiment of the present disclosure.

### DETAILED DESCRIPTION

In the following description and claims, the terms “coupled” and “connected,” along with their derivatives, may be used. In particular embodiments, “connected” and “coupled” may be used to indicate that two or more elements are in direct physical or electrical contact with each other, or may also mean that two or more elements may be in indirectly electrical contact with each other. The terms “coupled” and “connected” may still be used to indicate that two or more elements cooperate or interact with each other.

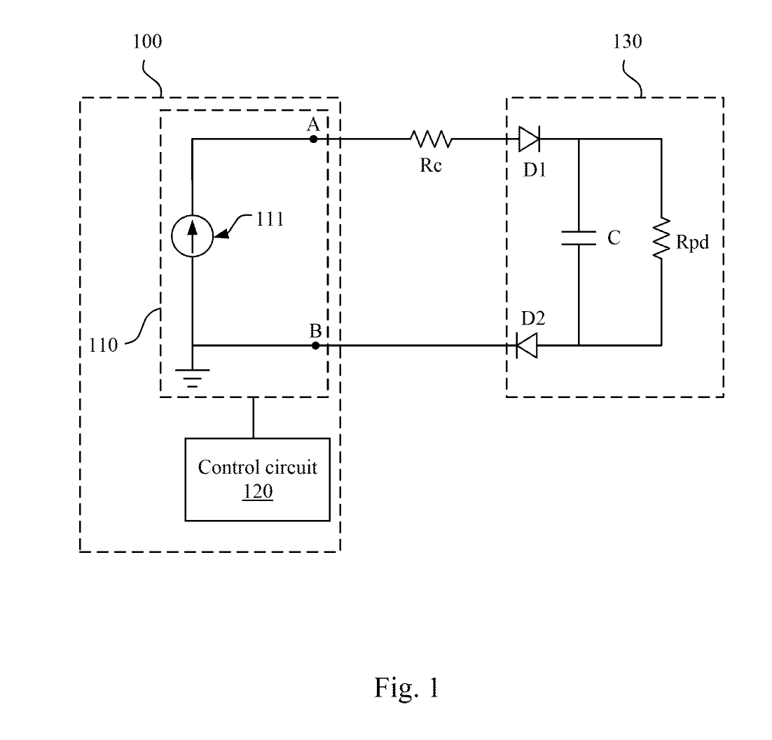

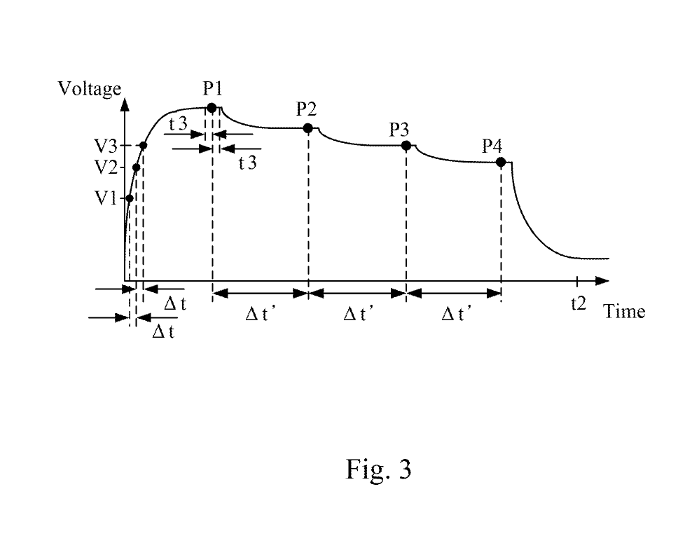

Reference is made to FIGS. 1 and 3. FIG. 1 is a schematic diagram of a detection device 100 according to an embodiment of the present disclosure. FIG. 3 is a schematic diagram of measurements according to an embodiment of the present disclosure. The detection device 100 includes a detection circuit 110 and a control circuit 120. The detection circuit 110 is coupled to the control circuit 120.

In an embodiment, the detection device 100 includes a current source 111. The control circuit 120 is configured to control the detection circuit 110 to provide a test current to a powered device (PD) 130 of a power over Ethernet (POE) system. For example, a resistor Rc may be an equivalent resistor of a network line. An equivalent circuit of the PD 130 includes a resistor Rpd, a capacitor C and diodes D1 and D2. The resistor Rpd is couple to the capacitor C in parallel. After the detection circuit 110 provides the test current to the PD 130, the detection circuit 110 measure a voltage between a node A and a node B. In some embodiments, a switch is disposed between the node B and a ground terminal.

As shown in FIG. 3, before the PD 130 reaches a steady state, the voltage between the node A and the node B shows an increasing trend. During a time interval after the PD 130 receives the test current and before the PD 130 reaches the steady state, the detection circuit 110 measures voltage values V1-V3 of the PD 130. In an embodiment, the detection circuit 110 is configured to measure the voltage values V1-V3 with a fixed time interval (e.g., first time interval Δt). It should be noted that the number of the voltage values V1-V3 measured by the detection circuit 110 are for example. However, the present disclosure is not limited thereto.

In an embodiment, the control circuit 120 is configured to calculate an equivalent resistance capacitance (RC) value of the PD 130 according to the voltage values V1-V3. For example, the control circuit 120 uses Eq. (1) to calculate the equivalent RC value (the voltage values V1-V3 are related to the resistor Rc; however, because resistance of the resistor Rc is much smaller than resistance of the resistor Rpd, the resistor Rc is omitted in Eq. (1)).

$$Rpd * C = \frac{Δ t}{ln ( \frac{V 2 - V 1}{V 3 - V 2} )} \qquad Eq . ( 1 )$$

It should be noted that left side of Eq. (1) is the equivalent RC value, Δt is the first time interval. In an embodiment, the control circuit 120 may determine can determine whether the measured voltage values V1-V3 are valid. For example, according to Eq. (1), if the control circuit 120 determines that the voltage value V1 is equal to the voltage value V2, the voltage value V2 is equal to the voltage value V3, or a voltage difference V2-V1 is equal to a voltage difference V3-V2, then the control circuit 120 determines that the voltage values V1-V3 are invalid. Moreover, when one of the voltage values V1, V2 and V3 exceeds a predetermined maximum voltage, the voltage values V1-V3 are also invalid. However, the present disclosure is not limited thereto.

In an embodiment, if the control circuit 120 determines that the voltage values V1-V3 are invalid, the control circuit 120 may control the detection circuit 110 to adjust the test current to another current value or maintain the original current value, and measure plural other voltage values (not shown) after the PD 130 receives the test current for the control circuit 120 calculating a resistance or a capacitance of the PD 130. Described with details, if the voltage value V1 is equal to the voltage value V2, the voltage value V2 is equal to the voltage value V3, or the voltage difference V2-V1 is equal to the voltage difference V3-V2, the control circuit 120 further controls the detection circuit 110 to adjust the test current to a larger current, and thereby determines that the PD 130 includes a capacitance or the PD 130 is short, and may further calculate a capacitance or a resistance (e.g., a resistance that is approaching to 0). In contrast, if one of the voltage values V1, V2 and V3 exceeds the predetermined maximum voltage, the control circuit 120 further controls the detection circuit 110 to adjust the test current to a smaller current, and thereby measures a resistance (e.g., approaching an open loop resistance).

In an embodiment, if the control circuit 120 determines that the voltage values V1-V3 are valid, the control circuit 120 is configured to determine a number of test currents used by the PD 130 in the steady state according to the voltage values V1-V3. For example, the control circuit 120 uses Eq. (2) to calculate the number of the test currents of the PD 130. It should be noted that the detection circuit 110 respectively measures at least one measured data under different test currents.

$$\frac{t 2}{4.6 * R * C} \qquad Eq . ( 2 )$$

It should be noted that R*C is the equivalent RC value calculated by the control circuit 120 through Eq. (1), t2 is the second time interval. In an embodiment, Eq. (2) is a derived according to IEEE 802.3af standard and IEEE 802.3at standard. Specifically, an error between a voltage of a measurement and a stable voltage should be within a range of 1% stable voltage. However, the present disclosure is not limited thereto. For example, in some embodiments, the detection circuit 110 performs measurement in a time interval t3 before or after a time point of the measured data P1 to obtain at least one measured data. In some embodiments, when a measuring point corresponds to plural measured data, the control circuit 120 averages the plural measured data to take the average as the measured data corresponding to the measuring point. However, the present disclosure is not limited thereto.

In an embodiment, the detection circuit 110 is configured to adjust the test current to a plurality of current values according to the number of the test currents in the second time interval t2 (e.g., 500 ms, however, the present disclosure is not limited thereto) to respectively generate at least one measured data (e.g., a voltage value) of the PD 130. In an embodiment, the control circuit 120 may calculate resistance (e.g., signature resistance) of the resistor Rpd of the PD 130 according to the measured data.

As a result, in the detection method of changing the test currents, the detection device 100 may first calculate the equivalent RC value of the PD device 130 to determine the number of the test currents of the PD 130, in order to insure that every measured data of resistance is measured when the PD 130 is in the steady state. Therefore, accuracy of calculating the resistor Rpd in the PD 130 by the detection device 100 can be effectively improved.

Because there may be an offset between the measured voltage by the detection circuit 110 and a voltage of the resistor Rpd of the PD 130, an error may therefore be generated by using single measuring point (e.g., single test current) to determine the resistance of the PD 130. In order to subtract the measured data corresponding to the measuring points from each other to eliminate the offset, in an embodiment, the control circuit 120 may determine whether the calculated number of the measuring points (e.g., number of the test currents) is larger than or equal to 2, and if the calculated number of the measured data is larger than or equal to 2, then the PD 130 performs resistance measurement.

For example, as shown in FIG. 3, a number of the measured data is 4, the detection circuit 110 is configured to adjust the test current to four current values to finish four measured data P1-P4 (i.e., four voltage measurements corresponding to the four current values) of the PD 130 with the same time interval Δt′ in the second time interval t2. For example, according to IEEE 802.3af standard and IEEE 802.3at standard, the time interval Δt′ is larger than or equal to (4.6*R*C). However, the present disclosure is not limited thereto. Therefore, in some embodiments, the detection device 100 may subtract two of the measured data P1-P4 from each other and divide the subtraction result by a current difference that is provided by the current source 111 to eliminate the offset, and then obtain the resistance of the resistor Rpd of the equivalent circuit of the PD 130 in the steady state. Accuracy of calculating the resistance of the resistor Rpd of the equivalent circuit of the PD 130 by using the detection device 100 in the present disclosure can be further improved.

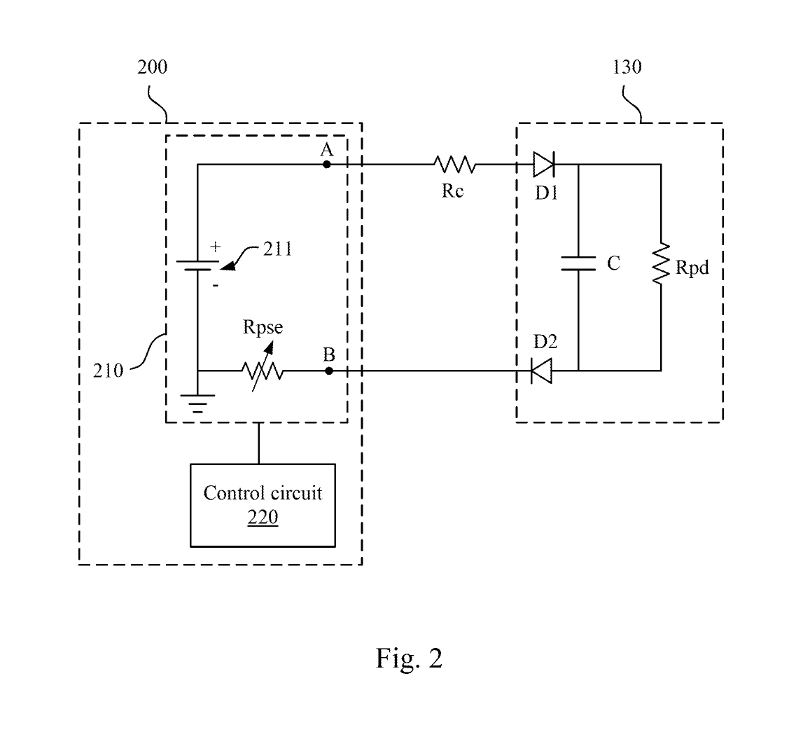

Reference is made to FIG. 2 to describe different methods of measuring the equivalent resistor Rpd of the PD 130. FIG. 2 is a schematic diagram of a detection device 200 in accordance with an embodiment of the present disclosure. The detection device 200 has similar configuration as configuration of the detection device 100 except that the detection circuit 210 includes a voltage source 211 and a resistor Rpse (e.g., a variable resistor). Description about different parts is made as follows, and the same part is not repeated herein.

In the present embodiment, the control circuit 220 may adjust resistance of the resistor Rpse to be voltage divided with the resistor Rpd of the equivalent circuit of the PD 130, and therefore the detection circuit 210 may measure different measured data according to different resistances (i.e., the test resistances) of the resistor Rpse. Specifically, the control circuit 220 first determines the resistance of the resistor Rpse, and controls the voltage source 211of the detection circuit 210 to provide a test voltage to the PD 130. After the detection circuit 210 provides the test voltage to the PD 130, the detection circuit 210 measures a current (e.g., current values I1-I3) that flows through the node B.

In an embodiment, the detection circuit 210 is configured to measure the current values I1-I3 with a fixed time interval (e.g., the first time interval Δt). It should be noted that the number of the current values I1-I3 measured by the detection circuit 210 is merely for example. However, the present disclosure is not limited herein.

In an embodiment, control circuit 220 is configured to calculate an equivalent RC value of the PD 130 and the detection circuit 210 according to the current values I1-I3. For example, the control circuit 220 uses Eq. (3) to calculate the equivalent RC value (because the resistance of the resistor Rc is much smaller than the resistance of the resistor Rpd, the resistor Rc is omitted in Eq. (3)).

$$\frac{Rpd * Rpse}{Rpd + Rpse} * C = \frac{Δ t}{ln ( \frac{I 2 - I 1}{I 3 - I 2} )} \qquad Eq . ( 3 )$$

It should be noted that left side of Eq. (3) is the equivalent RC value, and Δt is the first time interval. In an embodiment, the control circuit 220 may determine whether the measured current values I1-I3 are valid. For example, according to Eq. (3), if the control circuit 220 determines that the current value I1 is equal to the current value I2, the current value I2 is equal to the current value I3, or a current difference I2-I1 is equal to a current difference I3-I2, then the control circuit 220 determines that the current values I1-I3 are invalid. Moreover, when the current value I1, I2 or I3 is smaller than a predetermined current value (e.g., approaching to 0), the current values I1-I3 are also invalid. However, the present disclosure is not limited herein.

In an embodiment, if the control circuit 220 determines that the current values I1-I3 are invalid, then the control circuit 220 may control the detection circuit 210 to adjust the test resistor Rpse to another resistance or maintain the original resistance, and measure plural other current values (not shown) of the PD 130 after the PD 130 receives the test voltage for the control circuit 220 calculating the resistance or the capacitance of the PD 130.

Described with more details, if the current value I1 is equal to the current value I2 or the current value I2 is equal to the current value I3, the control circuit 220 determines that the PD 130 is short or merely includes a resistor. The control circuit 220 may control the detection circuit 210 to adjust the test resistor Rpse to another resistance or maintain the original resistance, and the resistor Rspe is used to be voltage divided to calculate the resistance of the PD 130. If the current difference I2-I1 is equal to the current difference I3-I2, and the current difference I2-I1 is not equal to 0, the control circuit 220 determines that the PD 130 includes a capacitor, and may obtain the capacitance according to a linear relation of the current values I1-I3. In contrast, if the current value I1, I2 or I3 is smaller than the predetermined current value, the control circuit 220 may control the detection circuit to adjust the resistor Rpse to a smaller resistor, for further determining whether the PD 130 is open.

In an embodiment, if the control circuit 120 determines that the current values I1-I3 are valid, the control circuit 220 is configured to determine the number of the test resistances of the PD 130 in the steady state according to the current values I1-I3. For example, the control circuit 220 uses the Eq. (3) to calculate the number of the test resistances.

It should be noted that R*C in Eq. (2) is the equivalent RC value calculated by the control circuit 220 through Eq. (3).

In an embodiment, the detection circuit 210 is configured to adjust a plurality of resistances of the test resistor Rpse to respectively generate plural measured data (e.g., current values) of the PD 130 according to the number of the test resistances in the second time interval t2 (e.g., 500 ms, however, the present disclosure is not limited herein). In an embodiment, the control circuit 220 may calculate the resistance (e.g., signature resistance) of the resistor Rpd of the PD 130 according to the measured data.

As a result, in the detection method of changing the resistance, the detection device 200 may first calculate the equivalent RC value of the PD 130 to determine the number of the test resistances, in order to insure every measured data is measured when the PD 130 is in the steady state. Therefore, accuracy of calculating the resistance of the resistor Rpd in the PD 130 by the detection device 200 can be effectively improved.

Alternatively, in another embodiment, the detection circuit 210 may measure different voltage values V1-V3 (e.g., voltage differences between the node A and the node B) when the resistor Rpse has different resistances for the control circuit 220 calculating equivalent RC value of the PD 130 and the detection circuit 210 according to Eq. (4) and calculating the number pf the test resistances according to Eq. (4).

$$\frac{Rpd * Rpse}{Rpd + Rpse} * C = \frac{Δ t}{ln ( \frac{V 2 - V 1}{V 3 - V 2} )} \qquad Eq . ( 4 )$$

It should be noted that left side of Eq. (4) is the equivalent RC value, and At is the first time interval. In an embodiment, the control circuit 220 may determine whether the measured voltage values V1-V3 are valid. For example, according to Eq. (4), if the control circuit 220 determines that the voltage value V1 is equal to the voltage value V2, the voltage value V2 is equal to the voltage value V3, or the voltage difference V2-V1 is equal to the voltage difference V3-V2, then the control circuit 220 determines that the voltage values V1-V3 are invalid. Moreover, when one of the voltage values V1, V2 and V3 exceeds a predetermined maximum voltage, the voltage values V1-V3 are also invalid. However, the present disclosure is not limited herein.

In practice, the control circuits 120 and 220 may include analog-to-digital converters (ADC). However, the present disclosure is not limited herein.

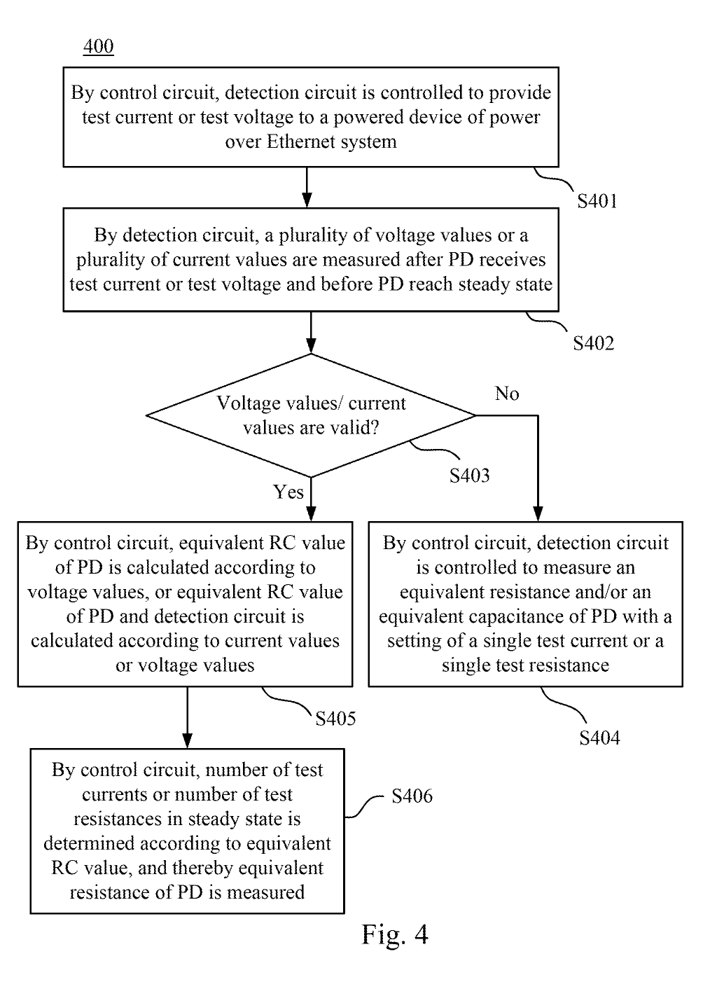

FIG. 4 is a flow chart illustrating a detection method 400 in accordance with an embodiment of the present disclosure. The detection method 400 for a POE system includes steps S401-S406, and the detection method 400 can be applied to the detection devices 100 and 200 as shown in FIGS. 1 and 2. However, those skilled in the art should understand that the mentioned steps in the present embodiment are in an adjustable execution sequence according to the actual demands except for the steps in a specially described sequence, and even the steps or parts of the steps can be executed simultaneously.

In step S401, by control circuits 120 and 220, detection circuits 110 and 210 are controlled to provide a test current or a test voltage to a PD 130 of the POE system.

In some embodiments, in step S401, when the detection circuit 210 provides the test current or the test voltage to the PD 130, a resistor Rpse of the detection circuit 210 maintain a fixed resistance first.

In step S402, by the detection circuits 110 and 210, a plurality of voltage values V1-V3 or a plurality of current values I1-I3 are measured after the PD 130 receives the test current or the test voltage and before the PD 130 reaches the steady state.

In step 403, by the control circuits 120 and 220, a determination whether the voltage values V1-V3 or the current values I1-I3 are valid is made. Standard for determination is described in above embodiments, and not be repeated herein.

If the voltage values V1-V3 or the current values I1-I3 are invalid, then in step S404, by the control circuits 120 and 220, the detection circuits 110 and 210 are controlled to measure an equivalent resistance and/or an equivalent capacitance of the PD 130 with a setting of a single test current or a single test resistance, and thereby determines whether the PD 130 is not a powered device (e.g., legacy PD) defined in IEEE 802.3af/IEEE 802.at, or determines whether connection ports of the detection devices 100 and 200 are short or open.

In some embodiments, the single test current may be an adjusted test current or the maintained original test current.

In some embodiments, the single test resistance may be an adjusted test resistance or the maintained test resistance.

In contrast, if the voltage values V1-V3 are valid, then in step S405, by the control circuit 120, an equivalent RC value of the PD 130 is calculated according to the voltage values V1-V3, or by the control circuit 220, an equivalent RC value of the PD 130 and the detection circuit 210 is calculated according to the current values I1-I3 or the voltage values V1-V3.

Then, in step S406, by the control circuits 120 and 220, a number of test currents or a number of test resistances in the steady state is determined according to the equivalent RC value, and thereby an equivalent resistance of the PD 130 is measured. In some embodiments, the detection circuits 110 and 210 may further obtain an equivalent capacitance of the PD 130 according to the equivalent RC value in Eq. (1) or Eq. (3).

In sum, the equivalent RC value of the PD 130 can be calculated first to determine the number of the test currents or the number of the test resistances of the PD 130 in the present disclosure, in order to insure that the measured data are measured when the PD 130 is in the steady state. Therefore, accuracy of calculating the resistance of the PD 130 is effectively improved in the present disclosure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A detection device for a power over Ethernet (POE) system, comprising:
a detection circuit configured to provide a first test current to a powered device (PD) of the POE system, and to measure a plurality of first voltage values after the PD receives the first test current and before the PD reaches a steady state; and
a control circuit configured to control the detection circuit to provide the first test current to the PD, and to determine a number of test currents used by the detection device in the steady state according to the first voltage values.

2. The detection device of claim 1, wherein the detection circuit is further configured to measure the first voltage values with a first time interval.

3. The detection device of claim 1, wherein the control circuit is further configured to calculate an equivalent resistance capacitance (RC) value of the powered device according to the first voltage values to determine the number of the test currents used by the detection device in the steady state.

4. The detection device of claim 3, wherein the equivalent RC value is calculated by using an equation as follows:
$$\frac{Δ t}{ln ( \frac{V 2 - V 1}{V 3 - V 2} )}$$
wherein Δt is the first time interval, and V1, V2 and V3 are the first voltage values.

5. The detection device of claim 3, wherein the detection circuit is further configured to adjust the first test current to a plurality of current values according to the number of the test currents in a second time interval to generate a plurality of measured data of the powered device, and the number of the test currents are calculated by an equation as follows:
$$\frac{t 2}{4.6 * R * C}$$
wherein t2 is the second time interval, and R*C is the equivalent RC value.

6. The detection device of claim 1, wherein if the control circuit determines that the first voltage values are in valid, the control circuit is further configured to provide a second test current to the PD to measure a plurality of second voltage value after the PD receives the second test current.

7. A detection device for a power over Ethernet (POE) system, comprising:
a detection circuit comprising a resistor and configured to provide a test voltage to a powered device (PD) of the POE system, and to measure a plurality of first current values or a plurality of first voltage values after the PD receives the test voltage and before the PD reaches a steady state; and
a control circuit configured to determine a first resistance of the resistor, to control the detection circuit to provide the test voltage to the PD, and to determine a number of test resistances used by the detection device in the steady state according to the first current values.

8. The detection device of claim 7, wherein the detection circuit is further configured to measure the first current values with a first time interval.

9. The detection device of claim 7, wherein the control circuit is further configured to calculate an equivalent resistance capacitance (RC) value of the PD and the detection circuit according to the first current values or the first voltage values to determine the number of the test resistances used by the detection device in the steady state.

10. The detection device of claim 9, wherein in a state where the detection circuit measures the first current values after the PD receives the test voltage and before the PD reaches the steady state, the equivalent RC value is calculated by using an equation as follows:
$$\frac{Δ t}{ln ( \frac{I 2 - I 1}{I 3 - I 2} )}$$
wherein Δt is the first time interval, and I1, I2 and I3 are the first current values.

11. The detection device of claim 9, wherein in a state where the detection circuit measures the first voltage values after the PD receives the test voltage and before the PD reaches the steady state, the equivalent RC value is calculated by using an equation as follows:
$$\frac{Δ t}{ln ( \frac{V 2 - V 1}{V 3 - V 2} )}$$
wherein Δt is the first time interval, and V1, V2 and V3 are the first voltage values.

12. The detection device of claims 10, wherein the detection circuit is configured to adjust the resistor to a plurality of resistances in a second time interval according to the number of the test resistances to generate a plurality of measured data of the PD, and the number of the test resistances is calculated by using an equation as follows:
$$\frac{t 2}{4.6 * R * C}$$
wherein t2 is the second time interval, and R*C is the equivalent RC value.

13. The detection device of claim 7, wherein if the control circuit determines that the first current values are invalid, the control circuit is further configured to adjust the resistor to a second resistance to measure a plurality of second current values of the powered device in a state where the resistor has the second resistance.

14. The detection device of claim 7, wherein if the control circuit determines that the first voltage values are invalid, the control circuit is further configured to adjust the resistor to a second resistance to measure a plurality of second voltage values of the powered device in a state where the resistor has the second resistance.

15. A detection method for a power over Ethernet (POE) system, comprising:
by a control circuit, controlling a detection circuit to provide a first test current to a powered device (PD) of the POE system; and
by the control circuit, determining a number of test currents used by the detection device in the steady state according to the first voltage values.

16. The detection method of claim 15, wherein by the detection circuit, measuring the first voltage value after the PD receives the first test current and before the PD reaches the steady state comprises:
by the detection circuit, measuring the first voltage values with a first time interval.

17. The detection method of claim 15, wherein by the control circuit, determining the number of the test currents used by the detection device in the steady state according to the first voltage values comprises:
by the control circuit, calculating an equivalent resistance capacitance (RC) value of the powered device according to the first voltage values to determine the number of the test currents used by the detection device in the steady state.

18. The detection method of claim 17, the equivalent RC value is calculated by using an equation as follows:
$$\frac{Δ t}{ln ( \frac{V 2 - V 1}{V 3 - V 2} )}$$
wherein Δt is the first time interval, and V1, V2 and V3 are the first voltage values.

19. The detection method of claim 17, further comprising:
by the detection circuit, adjusting the first test current to a plurality of current values according to the number of the test currents in a second time interval to generate a plurality of measured data of the powered device, wherein the number of the test currents are calculated by an equation as follows:
$$\frac{t 2}{4.6 * R * C}$$
wherein t2 is the second time interval, and R*C is the equivalent RC value.

20. The detection method of claim 15, further comprising:
if the control circuit determines that the first voltage values are invalid, by the control circuit, providing a second test current to the PD to measure a plurality of second voltage value after the PD receives the second test current.
